(19) United States
(12) Patent Application Publication
(10) Pub. No.: US 2004/0121545 A1
(43) Pub. Date: Jun. 24, 2004

(54) Method to fabricate a square word line poly spacer

(75) Inventors: Bi-Ling Chen, Taipei (TW); Hung-Cheng Sung, Hsin-Chu (TW); Chi-San Wu, Taipei (TW); Chia-Shiung Tsai, Hsin-Chu (TW); Hsiu Ouyang, Taipei (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/328,156

(22) Filed: Dec. 23, 2002

(51) Int. Cl. H01L 21/336

(52) U.S. Cl. 438/266; 438/267

(57) ABSTRACT

A new method is provided for the etch of polysilicon spacers that form part of split-gate flash memory devices. Under a first embodiment of the invention, a conventional polysilicon gate etch is augmented with an oxide based plasma treatment of the layer of polysilicon that is being etched as part of this etch. Under a second embodiment of the invention, a conventional five step etch procedure is replaced with a three step etch procedure that is based on SiON or SiN hardmask technology

### BACKGROUND OF THE INVENTION

(1) Field of the Invention

The invention relates to the fabrication of integrated circuit devices, and more particularly, to a structure for the creation of square word line poly spacers.

(2) Description of the Prior Art

Semiconductor device performance continues to be improved by virtue of reductions in device dimensions and by increasing device packaging densities. This also applies to the creation of CMOS devices, which from an essential part of flash memory devices.

Read Only Memory (ROM) devices are an importance part of devices that provide functions of data storage, these devices are also referred to as mask-programmed devices. ROM devices are non-volatile memories, indicating that data is permanently stored in the devices. Only read operations can be performed, changes of the data contained in the memory cannot be made after the device has been fabricated. Customization of the device is however economically feasible since only one mask needs to be used for the fabrication of the ROM device. ROM devices have been implemented using bipolar and CMOS technologies.

Different data are stored in a ROM device by the presence or the absence of a conductive data path between a word line (the access path of the memory) to a bit line (the sense line of the memory). No data element will be provided if the word line and the bit line are not interconnected by a circuit element. If therefore the word line of a ROM is activated, the presence of a signal on the bit line indicates that a “1” is stored in that data element (or bit location). The absence of a signal on the bit line indicates that a “0” is stored in that bit location.

Field-programmable ROM (PROM) devices are ROM devices that are typically manufactured in small quantities, using CMOS technology. These devices are programmed individually, some ROM devices are manufactured such that data, once entered into the device, cannot be erased. Other ROM devices allow the data to be erased and to be re-entered after the device has been manufactured. Erasable PROM (EPROM) devices depend on the long-term retention of data, the data is retained as an electronic charge and is stored on a polysilicon gate of a MOS device. The term “floating” in this structure refers to the fact that no electrical connection exists to the gate that retains the electrical charge. The charge is therefore transferred from the silicon substrate through an insulator. In order for the charge to be erased, the stored charge must be erased from the floating gate. EPROM cells typically consist of only one transistor, making it possible to create very high-density arrays of EPROM cells. To counter disadvantages of data erasure of conventional EPROM devices, electrically erasable PROM's (EEPROM's) have been created.

Most flash memory EEPROM devices use a double poly structure whereby the upper poly forms the control gate and the word lines of the structure while the lower poly is the floating gate. In a typical structure, the control-gate poly overlaps the channel region that is adjacent to the channel under the floating gate. The extension of the control gate over the channel region is referred to as the series enhancement-mode transistor and is required because when the cell is erased, a positive charge remains on the floating gate inverting the channel under floating gate. The series enhancement-mode transistor prevents the flow of current from the source to the drain regions of the MOS device.

Device performance improvements are typically achieved by reducing device dimensions, which further enables increased packaging density of the created semiconductor devices. It is therefore desirable to create memory devices that can be created over smaller surface regions of the substrate over which these devices are created. One of the frequently applied methods for the creation of etched layers of poly, that are part of a split gate flash memory device, is the use of a hardmask layer that overlies a layer of poly that needs to etched. For instance and specifically addressed by the invention, poly spacer must be created for the word line of a flash memory device. The shape of the poly spacer is of critical importance, whereby a gate spacer of essentially square cross section is advantageously created to avoid problems of punch through. The invention provides a method for the creation of square poly spacers for the created word line of the flash memory structure.

U.S. Pat. No. 5,915,178 (Chiang et al.) shows a related split gate process.

U.S. Pat. No. 6,165,845 (Hsieh et al.) teaches a split gate flash with a poly tip process.

U.S. Pat. No. 6,069,042 (Chien et al.) shows a multi-layer spacer process in split gate flash.

U.S. Pat. No. 6,312,989BI (I@sih et al.) shows a split gate flash with a poly spacer process.

U.S. Pat. No. 6,242,308 B1 (Hsieh et al.) shows a split gate flash with a spacer.

U.S. Pat. No. 6,001,690 (Chien et al.) and U.S. Pat. No. 6,204,126 B1 (Hsieh et al.) show related split gate flash processes.

### SUMMARY OF THE INVENTION

A principle objective of the invention is to provide a method for the creation of square word line polysilicon spacers for split-gate memory devices.

Another objective of the invention is to improve punch-through performance for split-gate flash memory devices.

Yet another objective of the invention is to improve insulation of split-gate flash memory devices.

A still further objective of the invention is to provide an improved barrier against impurity penetration into the surface of an underlying substrate for split-gate flash memory devices.

In accordance with the objectives of the invention a new method is provided for the etch of word line polysilicon spacers that form part of split-gate flash memory devices. Under a first embodiment of the invention, a conventional word line polysilicon gate etch is augmented with an oxygen plasma treatment of the layer of word line polysilicon that is etched as part of this etch. Under a second embodiment of the invention, a conventional five step etch procedure is replaced with a three step etch procedure that is based on SiON or hardmask technology.

### BRIEF DESCRIPTION OF THE DRAWINGS

FIG. 1a shows a cross section of a floating gate and a control gate of a conventional split-gate flash memory cell.

FIG. 1b shows a cross section of a conventional split-gate flash memory cell having two control gates overlying two floating gates.

FIG. 2 shows a cross section of a silicon substrate over the surface of which have been created a layer of gate oxide, a layer of poly-1 over which a photoresist mask has been created for the etching of the underlying two layers.

FIG. 3 shows a cross section after the layer of poly-2 has been etched, the photoresist mask has been removed.

FIG. 4 shows a cross section after a layer of interpoly oxide has been deposited and a layer of poly-2 has been etched in accordance with the invention for the creation of control gates.

### DESCRIPTION OF THE PREFERRED EMBODIMENTS

A conventional method of creating partially completed split-gate flash memory cell will first be briefly reviewed.

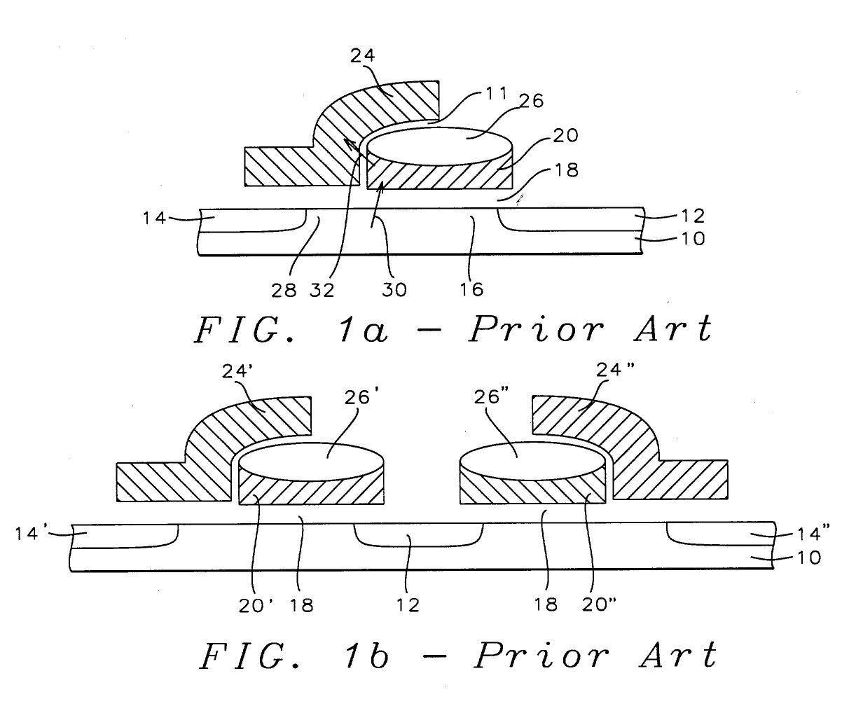

The cross section that is shown in FIG. 1a is referred to for this purpose, shown in the cross section of FIG. 1a is a conventional flash-memory cell in which a double-polysilicon (poly) structure is applied. A MOS transistor is formed on a semiconductor substrate 10 having a first doped region 12, also referred to as a Vss source region, a second doped region 14, also referred to as a drain region, a channel region 16, a layer 18 of gate oxide, a floating gate 20, a layer 22 of inter-gate dielectric and a control gate 24. Substrate 10 and channel region 16 have a first conductivity type, the first doped region 12 and the second doped region 14 have a second conductivity type that is opposite the first conductivity type of the substrate 10.

As seen in FIG. 1a, the first doped region 12 is provided in the surface of the substrate 10. The second doped region 14 is also provided in the surface of the substrate 10 and is spaced apart form the first doped region 12. The channel region 16 is in the surface of substrate 10 and is located between the first and the second doped regions, 12 and 14 respectively. Gate oxide layer 18 overlies the substrate 10. The floating gate 20, to which there is no direct electrical connection and which overlies the substrate 10, is separated from the substrate 10 by a thin layer 18 of gate oxide. The control gate 24, to which there is direct electrical connection, is generally positioned over the floating gate 20 with intergate oxide 22 provided between the floating gate 20 and the control gate 24.

The surface of the floating gate 20 has been highlighted as surface 26. Surface 26 typically is a layer of poly-oxide that has been formed over the surface of layer 20 of floating gate material by oxidizing the layer of semiconductor material 20 such as polysilicon that has been deposited for the creation of the floating gate 20, using methods of photolithography and exposure to expose layer 20 over surface area 26.

In the structure shown in FIG. 1a, control gate 24 overlaps the channel region 28, which is adjacent to channel 16 underneath the floating gate 20. This structure is needed because when the cell is erased, a positive charge is retained on the floating gate 20. As a result, the channel 16 under the floating gate 20 becomes inverted. The series MOS transistor (formed by the control gate 24 over the channel region 16) is needed in order to prevent current flow from the control gate 24 to the floating gate 20. The length of the transistor, that is the overlap 28 of the control gate 24 over the channel region 16, determines the cell performance.

To program the transistor shown in FIG. 1a, which shows the placement of a gate voltage Vg, a source voltage Vs and a drain voltages Vd, charge is transferred from substrate 10, through gate oxide 18 and is stored on floating gate 20 of the transistor. The amount of charge is set to one of two levels to indicate whether the cell has been programmed to an “on” or to an “off” condition. Reading of the programmed state of the cell is accomplished by applying appropriate voltages to the source 12 and drain 14 regions of the cell and to the control gate 24 after which the amount of charge on floating gate 20 is sensed. To erase the contents of the cell, the programming process is reversed, that is charges are removed from the floating gate 20 by transferring the charges back to the substrate 10 through the gate oxide 18. Electron tunneling occurs through the oxide regions 30 and 32 that have been highlighted in the cross section of FIG. 1a.

The programming and erasing of an EEPROM cell is accomplished electrically by using the familiar Fowler-Nordboirn (F-N) tunneling effect. During programming, a sufficiently high voltage is applied go to the control gate 24 and the drain 14 while the source 12 is grounded, creating a flow of electrons in the channel region 16 in the substrate 10. Some of these electrons gain enough energy to transfer from the substrate 10 to the floating gate 20 through the thin gate oxide layer 18 by means of Fowler-Nordheim tunneling. As the electron charge increases on the floating gate 20, the electric field between the control gate 24 and the drain 14 is reduced, which reduces the electron flow. Of importance in the tunneling region 30 and 32 is the quality and the thinness of the tunneling oxide 18 separating the floating gate 20 from the substrate 10. Inadvertent reverse tunneling, or erasure, for example, may occur if the tunnel oxide 18 is degraded, or other barriers to reverse tunneling are not formed in a split-gate flash memory cell.

A sidewall spacer (not shown) is typically provided over the exposed surface of the control gate 24 where this control gate does not overly the floating gate 20. It is the creation of this sidewall spacer that is addressed by the invention.

For the creation of the split-gate flash memory cell that is shown in cross section in FIG. 1a, the Vss source region 12 is first impurity implanted into the surface of substrate 10. A thin layer 18 of gate oxide is then formed over the surface of substrate 10 by either thermal oxidation or by a deposition process. The thin layer 18 of gate oxide essentially forms the tunneling layer of the memory cell. The floating gate 20 of a first conductivity type, typically comprising polysilicon, is then formed over the surface of the layer 18 of gate oxide. The pattern for the floating gate 20 is defined by a thick layer of oxide which is formed in similarity with the formation of a layer of LOCOS oxide.

The floating gate 20 is next covered with a layer 22 of inter-poly dielectric which forms the separation between the floating gate 20 and a thereover created control gate 24. For this layer 21 of spacer dielectric, a layer of Oxide/Nitride/Oxide (ONO) is frequently applied. The control gate 24, of a second conductivity type, is then formed overlying the layer 22 of spacer dielectric.

Where the cross section of FIG. 1a shows a split-gate flash memory device having a single floating gate and a single control gate, such a structure is conventionally and readily combined to form the structure that is shown in cross section in FIG. 1b. The cross section of FIG. 1b is shown to highlight that two floating gate 20′ and 20″, having surfaces 26′ and 26″, are symmetrically arranged adjacent to a commonly shared source region 12 while two control gates 24′ and 24″ are aligned with the two floating gates 20′ and 20″ and have each been provided with a drain region, highlighted as regions of impurity concentration 14′ and 14″ in the surface of substrate 10. Operational details and details of creation of the structure that is shown in cross section in FIG. 1b can readily be derived from and do not deviate from the description that has been provided for the cross section of FIG. 1a.

The invention specifically addresses the formation of word line poly spacers, since these word line poly spacers are created after the processing steps of FIGS. 1a and 1b for the creation of split gate flash memory devices have already been completed, these preliminary steps will be assumed to have preceded the steps that are of critical importance top the invention.

At the point in the creation of a split gate flash memory device that has proceeded through the steps as highlighted in FIGS. 1a and 1b, the device is now ready for the creation of word line poly spacers overlying sidewalls of the control gates 24′ and 24″ of FIG. 1b.

For this purpose, the invention provides two processing sequences, that is:

1. An in-situ O₂ plasma treatment is added to the conventional processing steps, this O₂ plasma treatment is applied to the layer of word line polysilicon (poly-2) and results in an improved profile of the created word lines, and

2. By using SiON or SiN hardmask technology, the need for additional processing to remove residue is eliminated.

The first of these two treatments, that is the in-situ O₂ plasma treatment, in effect comprises a boosting step to the conventional use of sacrificial hard mask material. This boosting of the conventional hard mask layer results in an improved profile of the created poly spacer layer of the word line. This in turn results in reducing the possibility of impurity implantation penetration since a layer of improved profile (more uniform thickness due to the more square cross section of the word line spacer layer blocks the impurity implantation where this self-aligned implantation is not designed to penetrate the surface of the underlying substrate. Further, the improved profile of the word line spacer results in creating a longer path between separate salicided surfaces, thus reducing the occurrence of the salicidation bridging.

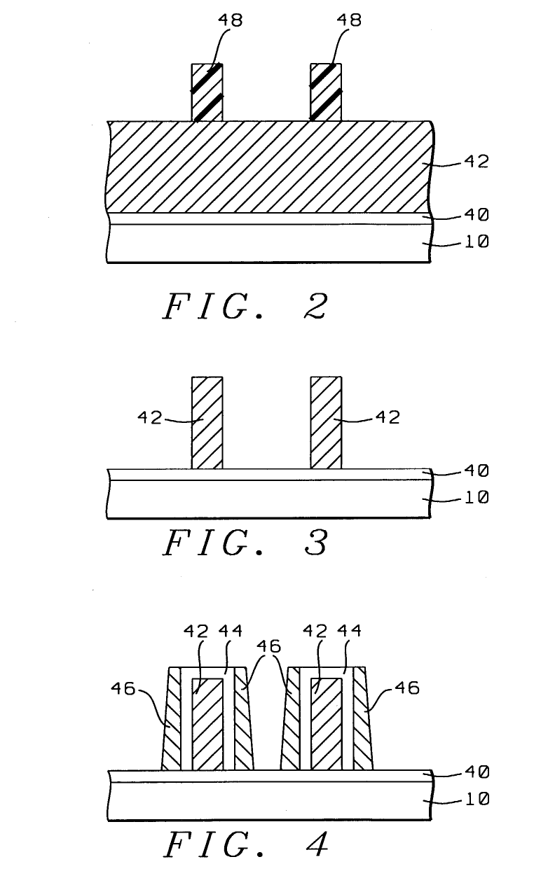

The process of the invention starts with a monocrystalline silicon semiconductor surface 10 as shown in cross section in FIG. 2, layer 40 of gate oxide has been formed over the surface of substrate 10 over which a layer 42 of poly-1 has been deposited. Before the creation of the highlighted layers, the surface of the substrate has been provided with regions of electrical insulation in the surface thereof such as regions of Shallow Trench Isolation (not shown) for the bounding of the active surface regions over the substrate 10 over which semiconductor devices are to be created. STI trenches are typically created to a depth of between about 2,500 Angstrom and 4,500 Angstrom and are thereafter filled with an isolation oxide such as silicon oxide.

Layer 40 of gate oxide is preferably created to a thickness between about 70 and 100 Angstrom, formed by thermal oxidation at a temperature between about 750 and 950 degrees C. The layer 40 of gate oxide can also be formed by an atmospheric or low pressure Chemical Vapor Deposition (APCVD/LPCVD).

The layer 42 of poly-1 is formed over the layer 40 of gate oxide through methods including but not limited to methods of LPCVD, Chemical Vapor Deposition (CVD) and Physical Vapor Deposition (PVD) sputtering methods employing suitable silicon source materials. Layer 42 of poly-1 is preferably formed using methods of LPCVD, using SiH₄ as a source material at a temperature range between about 530 and 560 degrees C.

A final layer 48 of photoresist mask is created over the surface of the layer 42 of poly-1, for the patterning and etching of layer 42 of poly-1. The photoresist mask 48, creates a pattern of poly-1 in the pattern of the layer of gate electrode material. After the layer 42 of poly-1 has been etched in accordance with the photoresist mask 48, the photoresist mask is removed from the surface of the layer 42 of poly-1, resulting in the cross section that is shown in FIG. 3.

Next, a layer 44 of interpoly oxide is deposited over the structure that is shown in cross section in FIG. 3, preferably formed at a temperature between about 750 and 900 degrees C. A second layer 46 of polysilicon, poly-2, is then formed over the substrate, to a thickness between about 1,500 and 2,000 Angstrom. The layer of poly-2 is etched to form the control gates 46 that are shown in cross section in FIG. 4.

The etching for the word line polysilicon gate spacers 46 conventionally uses a SiON or SiN sacrificial hard mask in combination with a three step or a five step etching sequence. The three step etch sequence typically comprises a Break Through etch (BT), followed by a Main Etch (ME) followed by an Overall Etch (OE). The five step etch procedure typically comprises the sequence of BT1-ME1-BT2-ME2-OE. The objective of this etch sequence is to create square-shaped poly spacers for split gate devices, the square shaped being required for reasons of device performance. The shape of the poly spacers is strongly related to the remaining hard mask thickness on the surface of the poly-2 surface during etching process. An insufficient hard mask layer on the layer of poly-2 results in a concave spacer profile.

To therefore create a poly spacer profile that is of a square cross section, the invention introduces an in-situ 02 plasma treatment to the surface of the deposited layer of poly-2, for the etching sequence of the word gate spacers, as part of the five steps of word line poly spacer etching, resulting in a square gate spacer profile. The complete steps as provided by the invention that incorporate a plasma treatment of the surface of the deposited layer of poly-2 is as follows:

BT1-ME1-in-situ O₂ plasma treatment-BT2-ME2-OE, whereby the applied processing conditions are as follows:

BT1 and BT2: a pressure of between about 2 and 15 mTorr, source power between about 100 and 1,000 Watt, bias power between about 10 and 200 Watt, etchant gas CF₄ supplied at between about 20- and 120 sccm

ME1 and ME2: a pressure of between about 2 and 15 mTorr, source power between about 100 and 1,000 Watt, bias power between about 10 and 250 Watt, etchant gas CF₄ supplied at between about 20 and 120 sccm with Cl₂ supplied at between about 15 and 150 sccm with HBr supplied at between about 20 and 120 sccm with He supplied at between about 3 and 30 sccm

OE: a pressure of between about 10 and 120 mTorr, source power between about 200 and 1,000 watt, bias power between about 15 and 250 Watt, etchant gas HBr supplied at between about 20 and 200 sccm with He—O₂ supplied at between about 2 and 15 sccm

in-Situ O₂ plasma treatment: a pressure of between about 2 and 100 mTorr, source power between about 200 and 1,000 Watt, bias power between about 10 and 200 Watt, source O₂ provided at between about 10 and 100 sccm.

The above provided in-situ O₂ plasma treatment provides a boost to the remaining sacrificial hard mask thickness by adding oxide to the layer of poly-² in order to create a poly spacer of square profile, as shown in cross section as elements 48 in FIG. 5.

The advantageous of square-profiled poly spacers can be summarized as follows:

1. the square profile avoids issues of implantation penetration since the square profile presents a uniform interface of uniform height between the source of impurities and the surface of the underlying substrate 10, and

2. the square profile avoids problems of salicidation shortage (due to salicided stringers) between contact surfaces of the split gate flash memory cell.

Under the second embodiment of the invention, the hardmask layer is improved by applying SiON or SiN hardmask technology.

The second embodiment of the invention teaches a three step etching procedure and therewith provides advantages of improved control of the etching sequence. The three step etch sequence of the second embodiment of the invention is as follows:

BT-ME-OE, whereby the applied processing conditions are as follows:

BT: a pressure of between about 2 and 15 mTorr, source power between about 100 and 1,000 Watt, bias power between about 15 200 Watt, etchant gas CF₄ supplied at between about 20 and sccm

ME: a pressure of between about 2 and 15 mTorr, source power between about 200 and 1,000 Watt, bias power between about 15 and 250 Watt, etchant gas CF₄ supplied at between about 5 and 100 sccm with Cl₂ supplied at between about 15 and 150 sccm with HBr supplied at between about 20 and 200 sccm with He supplied at between about 3 and 30 sccm

OE: a pressure of between about 10 and 120 mTorr, source power between about 200 and 1,000 Watt, bias power between about 15 and 250 Watt, etchant gas HBr supplied at between about 20 and 200 sccm with He—O₂ supplied at between about 2 and 15 sccm.

The advantages of the second embodiment of the invention can be summarized as follows:

1. By using SiON or SiN hardmask technology, the need for an additional mask that is typically required for the removal of residue, is eliminated

2. Punch-through of impurity implantations in the area surrounding the gate electrode is avoided

3. A three step etch sequence is more controllable than a five etch procedure, a five step etching procedure is prone to introduce particle contamination, and

4. The created square poly spacers provide a strong fence to the electrode and prevent issues of gate electrode defects.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method for the creation of word-line spacers for split-gate flash memory devices, comprising the steps of:
providing a substrate, at least one split-gate flash memory gate electrode structure having been created over the surface of said substrate;
depositing a layer of word line gate spacer material over the surface of said substrate, thereby including exposed surfaces of said at least one split-gate flash memory gate electrode structure; and
etching said layer of word line gate spacer material, thereby creating word line gate spacers for said at least one split-gate flash memory gate electrode structure.

2. The method of claim 1, said word line gate spacer material comprising polysilicon.

3. The method of claim 1, said etching said layer of word line gate spacer material comprising steps of:
a first Break Through etch (BT1);
first Main Etch (ME1);
in-situ O₂ plasma treatment;
a second Break Through etch (BT2);
a second Main Etch (ME2); and
an Overall Etch (OE).

4. The method of claim 3, said BT1 comprising applying a pressure of between about 2 and 15 mTorr, source power between about 100 and 1,000 Watt, bias power between about 10 and 200 Watt, etchant CF₄ supplied at between about 20 and 120 sccm.

5. The method of claim 3, said ME1 comprising applying a pressure of between about 2 and 15 mTorr, source power between about 100 and 1,000 Watt, bias power between about 10 and 250 Watt, etchant CF₄ supplied at between about 20 and 120 sccm with Cl₂ supplied at between about 15 and 150 sccm with HBr supplied at between about 20 and 120 sccm with He supplied at between about 3 and 30 sccm.

6. The method of claim 3, said in-situ O₂ plasma treatment comprising applying a pressure of between about 2 and 100 mTorr, source power between about 200 and 1,000 Watt, bias power between about 10 and 200 Watt, source O₂ provided at between about 10 and 100 sccm.

7. The method of claim 3, said BT2 comprising applying a pressure of between about 2 and 15 mTorr, source power between about 100 and 1,000 Watt, bias power between about 10 and 200 Watt, gas CF₄ supplied at between about 20 and 120 sccm.

8. The method of claim 3, said ME2 comprising applying a pressure of between about 2 and 15 mTorr, source power between about 100 and 1,000 Watt, bias power between about 10 and 250 Watt, etchant gas CF₄ supplied at between about 20 and 120 sccm with Cl₂ supplied at between about 15 and 150 sccm with HBr supplied at between about 20 and 120 sccm with He supplied at between about 3 and 30 sccm.

9. The method of claim 3, said Overall Etch (OE) comprising applying a pressure of between about 10 and 120 mTorr, source power between about 200 and 1,000 Watt, bias power between about 15 and 250 Watt, etchant gas HBr supplied at between about 20 and 200 sccm with He—O₂ supplied at between about 2 and 15 sccm.

10. A method for the creation of word-line spacers for split-gate flash memory devices, comprising the steps of:
providing a substrate;
creating a layer of gate oxide over the surface of said substrate;
depositing a first layer of gate material over the surface of said layer of gate oxide;
patterning and first etching said layer of first gate material creating floating gates for at least one split-gate flash memory gate electrode structure;
depositing a layer of inter-gate dielectric material over the surface of said substrate, thereby including exposed surfaces of said floating gates;
depositing a second layer of gate material over the surface of said layer of inter-gate dielectric material;
patterning and second etching said second layer of gate spacer material, creating control gates for said at least one split-gate flash memory gate electrode structure;
depositing a layer of word line gate spacer material over the surface of said substrate, thereby including exposed surfaces of said at least one split-gate flash memory gate electrode structure; and
third etching said layer of word line gate spacer material, thereby creating word line gate spacers for said at least one partially completed split-gate flash memory gate electrode structure, said third etching comprising an additional step of in-situ O₂ plasma treatment.

11. The method of claim 10, said first layer of gate material comprising polysilicon.

12. The method of claim 10, said second layer of gate material comprising polysilicon.

13. The method of claim 10, said word line gate spacer material comprising polysilicon.

14. The method of claim 10, said third etching comprising steps of:
a first Break Through etch (BT1);
a first Main Etch (ME1);
in-situ O₂ plasma treatment;
a second Break Through etch (BT2);
a second Main Etch (ME2); and
an Overall Etch (OE).

15. The method of claim 14, said BT1 comprising applying a pressure of between about 2 and 15 mTorr, source power between about 100 and 1,000 Watt, bias power between about 10 and 200 Watt, etchant gas CF₄ supplied at between about 20 and 120 sccm.

16. The method of claim 14, said ME1 comprising applying a pressure of between about 2 and 15 mTorr, source power between about 100 and 1,000 Watt, bias power between about 10 and 250 Watt, etchant gas CF₄ supplied at between about 20 and 120 sccm with Cl₂ supplied at between about 15 and 150 sccm with HBr supplied at between about 20 and 120 sccm with He supplied at between about 3 and 30 sccm.

17. The method of claim 14, said in-situ O₂ plasma treatment comprising applying a pressure of between about 2 and 100 mTorr, source power between about 200 and 1,000 Watt, bias power between about 10 and 200 Watt, source O₂ provided at between about 10 and 100 sccm.

18. The method of claim 14, said BT2 comprising applying a pressure of between about 2 and 15 mTorr, source power between about 100 and 1,000 Watt, bias power between about 10 and 200 Watt, etchant gas CF₄ supplied at between about 20 and 120 sccm.

19. The method of claim 14, said ME2 comprising applying a pressure of between about 2 and 15 mTorr, source power between about 100 and 1,000 Watt, bias power between about 10 and 250 Watt, etchant gas CF₄ supplied at between about 20 and 120 sccm, with Cl₂ supplied at between about 15 and 150 sccm with HBr supplied at between about 20 and 120 sccm with He supplied at between about 3 and 30 sccm.

20. The method of claim 14, said Overall Etch (OE) comprising applying a pressure of between about 10 and 120 mTorr, source power between about 200 and 1,000 Watt, bias power between about 15 and 250 Watt, etchant gas HBr supplied at between about 20 and 200 sccm with He—O₂ supplied at between about 2 and 15 sccm.

21. The method of claim 1, said etching said layer of word line gate spacer material comprising steps of:
a Break Through etch (BT); then
a Main Etch (ME); and then
an Overall Etch (OE).

22. The method of claim 21, said etching said layer of word line gate spacer material further comprising an in-situ O₂ plasma treatment.

23. The method of claim 21, said BT comprising applying a pressure of between about 2 and 15 mtorr, source power between about 100 and 1,000 Watt, bias power between about 15 and 200 Watt, etchant gas CF₄ supplied at between about 20 and 120 sccm.

24. The method of claim 21, said ME comprising applying a pressure of between about 2 and 15 mTorr, source power between about 200 and 1,000 Watt, bias power between about 15 and 250 Watt, etchant gas CF₄ supplied at between about 5 and 100 sccm with Cl₂ supplied at between about 15 and 150 sccm with HEr supplied at between about 20 and 200 sccm with He supplied at between about 3 and 30 sccm.

25. The method of claim 21, said Overall Etch (OE) comprising applying a pressure of between about 10 and 120 mTorr, source power between about 200 and 1,000 Watt, bias power between about 15 and 250 Watt, etchant gas HBr supplied at between about 20 and 200 sccm with He—O₂ supplied at between about 2 and 15 sccm.

26. A method for the creation of word-line spacers for split-gate flash memory devices, comprising the steps of:
providing a substrate;
creating a layer of gate oxide over the surface of said substrate;
depositing a first layer of gate material over the surface of said layer of gate oxide;
patterning and first etching said layer of first gate material, creating floating gates for at least one split-gate flash memory gate electrode structure;
depositing a layer of inter-gate dielectric material over the surface of said substrate, thereby including exposed surfaces of said floating gates;
depositing a second layer of gate material over the surface of said layer of inter-gate dielectric material;
patterning and second etching said second layer of gate spacer material, creating control gates for said at least one split-gate flash memory gate electrode structure;
depositing a layer of word line gate spacer material over the surface of said substrate, thereby including exposed surfaces of said at least one split-gate flash memory gate electrode structure; and
third etching said layer of word line gate spacer material, thereby creating word line gate spacers for said at least one partially completed split-gate flash memory gate electrode structure, said third etching said layer of word line gate spacer material comprising a three step etch procedure.

27. The method of claim 26, said first layer of gate material comprising polysilicon.

28. The method of claim 26, said second layer of gate material comprising polysilicon.

29. The method of claim 26, said word line gate spacer material comprising polysilicon.

30. The method of claim 26, said third etching comprising steps of:
a Break Through etch (BT); then
a Main Etch (ME); and then
an Overall Etch (OE).

31. The method of claim 30, said etching said layer of word line gate spacer material further comprising an in-situ O₂ plasma treatment.

32. The method of claim 30, said BT comprising applying a pressure of between about 2 and 15 mTorr, source power between about 100 and 1,000 Watt, bias power between about 15 and 200 Watt, etchant gas CF₄ supplied at between about 20 and 120 sccm.

33. The method of claim 30, said ME comprising applying a pressure of between about 2 and 15 mTorr, source power between about 200 and 1,000 Watt, bias power between about 15 and 250 Watt, etchant gas CF₄ supplied at between about 5 and 100 sccm with Cl₂ supplied at between about 15 and 150 sccm with HBr supplied at between about 20 and 200 sccm with He supplied at between about 3 and 30 sccm.

34. The method of claim 30, said Overall Etch (OE) comprising applying a pressure of between about 10 and 120 mTorr, source power between about 200 and 1,000 Watt, bias power between about 15 and 250 Watt, etchant gas HBr supplied at between about 20 and 200 sccm with He—O₂ supplied at between about 2 and 15 sccm.
